(19) United States
(12) Patent Application Publication
(10) Pub. No.: US 2015/0353413 A1
(43) Pub. Date: Dec. 10, 2015

(54) CRYSTALLINE GLASS SUBSTRATE, CRYSTALLIZED GLASS SUBSTRATE, DIFFUSION PLATE, AND ILLUMINATION DEVICE PROVIDED WITH SAME

(71) Applicant: NIPPON ELECTRIC GLASS CO., LTD., Otsu-shi, Shiga (JP)

(72) Inventors: Atsushi MUSHIAKE, Shiga (JP); Tai FUJISAWA, Shiga (JP); Yohei HOSODA, Shiga (JP)

(21) Appl. No.: 14/760,532

(22) PCT Filed: Jan. 16, 2014
(86) PCT No.: PCT/JP2014/050659

§ 371 Date: Jul. 13, 2015

(30) Foreign Application Priority Data
Jan. 18, 2013 (JP) 2013-006861
Jan. 18, 2013 (JP) 2013-007215

(51) Int. Cl. C03C 3/097; C03C 3/087; H01L 51/52; C03B 32/02

(52) U.S. Cl. CPC C03C 3/097; C03B 32/02; C03C 3/087; H01L 51/5268

(57) ABSTRACT

Devised is a substrate material that allows an OLED element to have enhanced light extraction efficiency without forming a light extracting layer formed of a sintered compact, and exhibits excellent productivity. A crystallizable glass substrate (1) is used as the substrate material and applied to an OLED illumination device.

### TECHNICAL FIELD

The present invention relates to a crystallizable glass substrate and crystallized glass substrate capable of imparting a light scattering function, and to a diffusion plate and an illumination device comprising the diffusion plate.

### BACKGROUND ART

In recent years, more and more energy has been consumed in a living space such as a home owing to, for example, spread, an increase in size, or multifunctionalization of home appliances. In particular, energy consumption of an illumination device has been increased. Therefore, an illumination device having high efficiency has been actively studied.

Light sources for illumination are divided into “a directional light source” for illuminating a limited area and “a diffuse light source” for illuminating a wide area. An LED illumination device corresponds to the “directional light source” and has been adopted as an alternative to an incandescent lamp. On the other hand, an alternative light source to a fluorescent lamp, which corresponds to the “diffuse light source,” has been demanded, and its potential candidate is an organic electroluminescence (EL) (OLED) illumination device.

FIG. 3 is a conceptual sectional view of an OLED illumination device 10. The OLED illumination device 10 is an element comprising: a glass sheet 11; a transparent conductive film as an anode 12; an OLED layer 13 including one or a plurality of light emitting layers each formed of an organic compound exhibiting electroluminescence upon injection of an electrical current; and a cathode. For the OLED layer 13 to be used in the OLED illumination device 10, a low-molecular-weight coloring matter-based material, a conjugated polymer-based material, or the like is used. The light emitting layer is formed as a laminated structure with a hole injection layer, a hole transport layer, an electron transport layer, an electron injection layer, or the like. The OLED layer 13 having such laminated structure is arranged between the anode 12 and a cathode 14. When an electric field is applied between the anode 12 and the cathode 14, a hole injected from a transparent electrode as the anode 12 and an electron injected from the cathode 14 recombine in the light emitting layer, and light is emitted upon excitation of a light emission center by recombination energy.

An OLED element has been studied for applications to a mobile phone or a display, and some of the OLED elements have already been put in practical use.

In addition, the OLED element has luminous efficiency comparable to that of a flat panel television using a liquid crystal display, a plasma display, or the like. However, its brightness does not still reach a practical level in view of an application to the light source for illumination. Therefore, the luminous efficiency is required to be further improved.

One reason for low brightness is mismatch of refractive indices. Specifically, an OLED layer has a refractive index nd of from 1.8 to 1.9, and a transparent conductive film has a refractive index nd of from 1.9 to 2.0. In contrast, a glass substrate generally has a refractive index nd of about 1.5. Therefore, a related-art OLED device has a problem of low light extraction efficiency, because the refractive indices of the transparent conductive film and the glass substrate are largely different from each other, and hence light radiated from the OLED layer is reflected at an interface between the transparent conductive film and the glass substrate.

In addition, another reason for the low brightness is that light is trapped in the glass substrate owing to a difference in refractive index between the glass substrate and air. For example, when a glass substrate having a refractive index nd of 1.5 is used, a critical angle is calculated to be 42° by Snell's law based on the refractive index nd of air, 1.0. Therefore, light entering at an incident angle equal to or more than the critical angle is supposed to be totally reflected, trapped in the glass substrate, and not extracted into air.

### CITATION LIST

Patent Literature 1: JP 2012-25634 A

Patent Literature 2: JP 2010-198797 A

### SUMMARY OF INVENTION

### Technical Problem

In order to solve the above-mentioned problems, studies have been made en formation of a light extracting layer between the transparent conductive film and the glass substrate. For example, Patent Literature 1 discloses that a light extracting layer obtained by sintering a glass frit having a high refractive index is formed on the surface of a soda glass substrate in order to enhance the light extraction efficiency. Further, Patent Literature 1 discloses that the light extraction efficiency is further enhanced by diffusing a scattering substance in the light extracting layer. In addition, Patent Literature 2 discloses that a light extracting layer is formed by, after forming irregularities on the surface of a glass sheet, sintering a glass frit having a high refractive index on the irregularities.

However, the glass frit disclosed in Patent Literature 1 has high raw material cost because of containing Nb₂O₅ and the like in large amounts. In addition, the formation of the light extracting layer on the surface of the glass substrate requires a printing step of applying glass paste onto the surface of the glass substrate. The printing step raises the production cost. Further, in the case of diffusing scattering particles in the glass frit, the transmittance of the light extracting layer lowers owing to absorption by the scattering particles themselves.

In addition, the production of the glass sheet disclosed in Patent Literature 2 requires a step of forming the irregularities on the surface of the glass sheet, and as well, a printing step of applying glass paste onto the irregularities. Those steps raise the manufacturing cost.

The present invention has been made in view of the above-mentioned circumstances, and a technical object of the present invention is to devise a substrate material that allows an OLED element to have enhanced light extraction efficiency without forming a light extracting layer formed of a sintered compact, and exhibits excellent productivity.

### Solution to Problem

As a result of diligent studies, the inventors of the present invention have found that, when a crystallizable glass substrate is crystallized and the obtained crystallized glass is applied to an OLED illumination device, the light extraction efficiency is improved without forming a light extracting layer formed of a sintered compact, because light radiated from an OLED layer is scattered at the interface between a glass matrix and a precipitated crystal. Thus, the finding is proposed as the present invention. Specifically, in the present invention, a crystallizable glass substrate is used as the substrate material and applied to an OLED illumination device. Herein, the “crystallizable” refers to property of precipitating a crystal through heat treatment.

In this case, it is preferred that the crystallizable glass substrate of the present invention comprise as a glass composition, in terms of mass %, 40 to 80% of SiO₂, 10 to 35% of Al₂O₃, and 1 to 10% of Li₂O. With this, a Li₂O—Al₂O₃—SiO₂-based crystal (LAS-based crystal: for example, a β-quartz solid solution or a β-spodumene solid solution) can be precipitated as a main crystal through heat treatment. As a result, a light scattering function can be ensured. Besides, the thermal expansion coefficient in a temperature range of from 30 to 750° C. ranges from −10×10⁻⁷ to 30×10⁻⁷/° C., and hence thermal shock resistance can be enhanced.

Further, it is preferred that the crystallizable glass substrate of the present invention comprise as a glass composition, in terms of mass %, 55 to 73% of SiO₂, 17 to 27% of Al₂O₃, 2 to 5% of Li₂O, 0 to 1.5% of MgO, 0 to 1.5% of ZnO, 0 to 1% of Na₂O, 0 to 1% of K₂O, 0 to 3.8% of TiO₂, 0 to 2.5% of ZrO₂, and 0 to 0.6% of SnO₂.

In addition, it is preferred that the crystallizable glass substrate of the present invention be substantially free of As₂O₃ and Sb₂O₃. With this, environmental demands of recent years can be satisfied. Herein, the “substantially free of As₂O₃” refers to the case where the content of As₂O₃ in the glass composition is less than 0.1 mass %. The “substantially free of Sb₂O₃” refers to the case where the content of Sb₂O₃ in the glass composition is less than 0.1 mass %.

Further, it is preferred that the crystallizable glass substrate of the present invention have a thickness of 2.0 mm or less. With this, an OLED illumination device can be easily reduced in weight.

In addition, it is preferred that the crystallizable glass substrate of the present invention have a refractive index nd of more than 1.500. This reduces a difference in refractive index at the interface between the OLED layer and the crystallized glass substrate, and hence light radiated from the OLED layer is hardly reflected at the interface between a transparent conductive film and the crystallized glass substrate. Herein, the “refractive index nd” may be measured with a refractive index measuring device. For example, a rectangular sample measuring 25 mm×25 mm×about 3 mm is produced, and then the sample is subjected to annealing treatment in a temperature range of from (annealing point Ta+30° C.) to (strain point Ps-50° C.) at a cooling rate of 0.1° C./min. After that, the refractive index may be measured by using a refractive index measuring device KPR-2000 manufactured by Kalnew Optical Industrial Co., Ltd., while an immersion liquid having a matched refractive index nd is allowed to penetrate into glass.

Further, it is preferred that the crystallizable glass substrate of the present invention be formed by a roll out method. This enables mass-production of a large-size crystallizable glass substrate. Herein, the “roll out method” refers to a method of forming a glass substrate, involving sandwiching molten glass between a pair of forming rolls, followed by rolling forming while the molten glass is quenched.

In addition, it is preferred that the crystallizable glass substrate of the present invention be formed by a float method. This can enhance the surface smoothness of the crystallizable glass substrate (in particular, the surface smoothness on a glass surface side prevented from being brought into contact with a molten metal bath of tin). Herein, the “float method” refers to a method of forming a glass substrate, involving floating molten glass on a molten metal bath of tin (float bath).

Further, a crystallized glass substrate of the present invention is obtained by subjecting a crystallizable glass substrate to heat treatment, the crystallizable glass substrate comprising the above-mentioned crystallizable glass substrate.

In addition, if is preferred that the crystallized glass substrate of the present invention comprise as a main crystal a β-quartz solid solution or a β-spodumene solid solution. With this, a light scattering function can be ensured. Besides, the thermal expansion coefficient in a temperature range of from 30 to 750° C. ranges from −10×10⁻⁷ to 30×10⁻⁷/° C., and hence thermal shock resistance can be enhanced. Herein, the “main crystal” refers to a crystal precipitated in the largest amount.

Further, it is preferred that the crystallized glass substrate of the present invention have an average crystal grain size of from 10 to 2,000 nm. With this, a light scattering function in a visible light range is easily enhanced.

In addition, it is preferred that the crystallized glass substrate of the present invention have a haze value of 0.2% or more. With this, light radiated from the OLED layer is easily scattered in the crystallized glass substrate. Herein, the “haze value” may be measured by, for example, using as an evaluation sample a sample (thickness: 1.1 mm) having both surfaces mirror polished, with a TM double beam type automatic haze computer manufactured by Suga Test Instruments Co., Ltd.

Further, it is preferred that the crystallized glass substrate of the present invention have such property that light is extracted from one surface of the crystallized glass substrate, when the light enters from another surface of the crystallized glass substrate at a critical angle or more. With this, light to be trapped in the crystallized glass substrate is reduced, and hence the light extraction efficiency is improved.

In addition, it is preferred that the crystallized glass substrate of the present invention have a value represented by (a radiation flux value to be obtained from one surface of the crystallized glass substrate, when light is radiated from another surface of the crystallized glass substrate at an incident angle of 60°)/(a radiation flux value to be obtained from one surface of the crystallized glass substrate, when light is radiated from another surface of the crystallized glass substrate at an incident angle of 0°) of 0.005 or more. With this, light to be trapped in the crystallized glass substrate is reduced, and hence the light extraction efficiency is improved.

Further, a manufacturing method for a crystallized glass substrate of the present invention comprises subjecting the above-mentioned crystallizable glass substrate to heat treatment, to obtain a crystallized glass substrate, in the heat treatment, the crystallizable glass substrate being maintained in a crystal growth temperature range (for example, 800 to 1,100° C.) for the crystallizable glass substrate for 30 minutes or more and being prevented from being maintained in a crystal nucleation temperature range (for example, 600° C. to less than 800° C.) for the crystallizable glass substrate for 30 minutes or more. With this, a crystal nucleus is prevented from being precipitated in the glass matrix in a large amount, and hence the average crystal grain size per crystal grain easily becomes large. As a result, a crystal grain can be coarsened to the extent that the light scattering function is exhibited in a visible light range.

In addition, as a result of diligent studies, the inventors of the present invention have found that, when a number of fine crystals are precipitated in a glass substrate comprising Al₂O₃ and/or SiO₂ through heat treatment, and such glass substrate is used as a diffusion plate, the light extraction efficiency of an OLED illumination device or the like can be enhanced because emitted light is scattered at the interface between matrix glass and the fine crystals. Thus, the finding is proposed as the present invention. That is, a diffusion plate of the present invention comprises a crystallized glass substrate obtained by subjecting the above-mentioned crystallizable glass substrate to heat treatment, the crystallized glass substrate comprising as a composition at least Al₂O₃ and/or SiO₂ and having a crystallinity of from 10 to 90%. Herein, the “crystallized glass substrate” includes not only one having a flat sheet shape, but also one having a substantially sheet shape with a bent portion, a stepped portion, or the like. The “crystallinity” refers to a value obtained by the following procedure: XRD is measured by a powder method, and the area of a halo corresponding to the mass of an amorphous portion and the area of a peak corresponding to the mass of a crystal are calculated; and then, the crystallinity is determined based on the expression [area of peak]×100/[area of peak+area of halo](%).

In this case, the diffusion plate of the present invention comprises a crystallized glass substrate comprising at least Al₂O₃ and/or SiO₂. With this, weather resistance can be enhanced. In addition, in the diffusion plate of the present invention, the crystallized glass substrate has a crystallinity of from 10 to 90%. With this, a visible light scattering function can be enhanced. Further, the diffusion plate of the present invention can be produced by subjecting a glass sheet to heat treatment to achieve its crystallization. Therefore, the manufacturing cost of the diffusion plate can be reduced.

Further, it is preferred that the diffusion plate of the present invention comprise as a main crystal an Al—Si—O-based crystal, Herein, the “main crystal” refers to a crystal species precipitated at the largest ratio in an XRD pattern. The “-based crystal” refers to a crystal comprising as an essential component the explicit component, and is preferably a crystal substantially free of a component other than the explicit component.

In addition, it is preferred that the diffusion plate of the present invention comprise as a main crystal an R—Al—Si—O-based crystal. Herein, “R” refers to any one of Li, Na, K, Mg, Ca, Sr, Ba, and Zn.

Further, it is preferred that the diffusion plate of the present invention comprise as a composition, in terms of mass %, 45 to 75% of SiO₂, 13 to 30% of Al₂O₃, and 0 to 30% of Li₂O+Na₂O+K₂O+MgO+CaO+SrO+BaO+ZnO. Herein, “Li₂O+Na₂O+K₂O+MgO+CaO+SrO+BaO+ZnO” refers to the total content of Li₂O, Na₂O, K₂O, MgO, CaO, SrO, BaO, and ZnO.

In addition, it is preferred that the diffusion plate of the present invention comprise as a composition, in terms of mass %, 45 to 70% of SiO₂, 13 to 30% of Al₂O₃, and 1 to 35% of Li₂O+Na₂O+K₂O+MgO+CaO+SrO+BaO+ZnO.

Further, it is preferred that the diffusion plate of the present invention have an average crystal grain size of a main crystal of from 20 to 30,000 nm.

In addition, it is preferred that the diffusion plate of the present invention have a haze value of 10% or more. Herein, the “haze value” refers to a ratio of diffuse transmitted light to the total transmitted light. A lower haze value represents higher transparency. The haze value may be measured by, for example, using as an evaluation sample a sample (thickness: 1 mm) having both, surfaces mirror polished, with a TM double beam type automatic haze computer manufactured by Suga Test Instruments Co., Ltd.

Further, it is preferred that the diffusion plate of the present invention be used for an illumination device.

In addition, it is prefer red that an illumination device of the present invention comprise the above-mentioned diffusion plate. The illumination device of the present invention allows for scattering of emitted light and can exhibit enhanced, light extraction efficiency, by virtue of comprising the diffusion, plate. As a result, a reduction in the amount of an electric current is achieved. This allows the illumination device to have a prolonged lifetime and enjoy an energy saving effect.

### BRIEF DESCRIPTION OF DRAWINGS

FIG. 1 is a schematic sectional view illustrating an evaluation method for a light scattering function.

FIG. 2 is a chart in which data in [Table 5] are plotted.

FIG. 3 is a conceptual sectional view of an OLED illumination device.

### DESCRIPTION OF EMBODIMENTS

A crystallizable glass substrate of the present invention preferably comprises as a glass composition, in terms of mass %, 40 to 80% of SiO₂, 10 to 35% of Al₂O₃, and 1 to 10% of Li₂O. The reasons why the contents of the components are specified as described above are hereinafter described. It should be noted that a crystallized glass substrate of the present invention preferably has the same composition as that of the crystallizable glass substrate of the present invention.

SiO₂ is a component that forms the skeleton of glass and serves as a constituent of a LAS-based crystal. When the content of SiO₂ is small, chemical durability is liable to lower. In contrast, when the content of SiO₂ is large, meltability is liable to lower or the viscosity of molten glass is liable to increase. As a result, it is difficult to form the crystallizable glass substrate. Therefore, the content of SiO₂ is preferably from 40 to 80%, from 50 to 75%, from 55 to 73%, or from 58 to 70%, particularly preferably from 60 to 68%.

Al₂O₃ is a component that forms the skeleton of the glass and serves as a constituent of the LAS-based crystal. When the content of Al₂O₃ is small, the chemical durability is liable to lower. In contrast, when the content of Al₂O₃ is large, the meltability is liable to lower or the viscosity of the molten glass is liable to increase. As a result, it is difficult to form the crystallizable glass substrate. In addition, the glass is liable to be broken owing to a crystal of mullite to be precipitated during forming. Therefore, the content of Al₂O₃ is preferably from 10 to 35%, from 1 to 27%, or from 19 to 25%, particularly preferably from 20 to 23%.

Li₂O is a component that serves as a constituent of the LAS-based crystal, has a large impact on its crystallinity, and enhances the meltability and formability by lowering the viscosity of the glass. When the content of Li₂O is small, the LAS-based crystal is hardly precipitated during heat treatment. Further, the glass is liable to be broken owing to a crystal of mullite to be precipitated during forming. In contrast, when the content of Li₂O is large, the crystallinity becomes excessively high, and the glass is devitrified during forming. As a result, the glass is liable to be broken. Therefore, the content of Li₂O is preferably from 1 to 10%, from 2 to 5%, or from 2.3 to 4.7%, particularly preferably from 2.5 to 4.5%.

For example, the following components may be added in addition to the above-mentioned components.

MgO is a component that is dissolved as a solid solution in the LAS-based crystal. When the content of MgO is large, the crystallinity becomes excessively high, and the glass is devitrified during forming. As a result, the glass is liable to be broken. Therefore, the content of MgO is preferably from 0 to 5% or from 0 to 1.5%, particularly preferably from 0 to 1.2%.

ZnO is a component that increases a refractive index, and is also a component that is dissolved as a solid solution in the LAS-based crystal as with MgO. When the content of ZnO is large, the crystallinity becomes excessively high, and the glass is devitrified during forming. As a result, the glass is liable to be broken. Therefore, the content of ZnO is preferably from 0 to 5%, from 0 to 3%, or from 0 to 1.5%, particularly preferably from 0 to 1.2%.

When the total content of Li₂O, MgO, and ZnO is too small, the glass is liable to be broken owing to a crystal of mullite to be precipitated during forming. Further, the LAS-based crystal is hardly precipitated during crystallization of the crystallizable glass, and the thermal shock resistance of the crystallized glass substrate is liable to lower. In contrast, when the total content of Li₂O, MgO, and ZnO is large, the crystallinity becomes excessively high, and the glass is devitrified during forming. As a result, the glass is liable to be broken. Therefore, the total content of Li₂O, MgO, and ZnO is preferably from 1 to 10% or from 2 to 5.2%, particularly preferably from 2.3 to 5%.

Na₂O is a component that enhances the meltability and the formability by lowering the viscosity of the glass. When the content of Na₂O is large, Na₂O is trapped in a β-spodumene solid solution during forming, and crystal growth is promoted. This causes devitrification of the glass, and the glass is liable to be broken. Therefore, the content of Na₂O is preferably from 0 to 3%, from 0 to 1%, or from 0 to 0.6%, particularly preferably from 0.05 to 0.5%.

K₂O is a component that enhances the meltability and the formability by lowering the viscosity of the glass. When the content of K₂O is large, a thermal expansion coefficient is liable to increase, and creep resistance is liable to lower. As a result, the crystallized glass substrate is liable to be deformed when used at high temperature for a long period of time. Therefore, the content of K₂O is preferably from 0 to 3%, from 0 to 1%, or from, 0 to 0.6%, particularly preferably from 0.05 to 0,5%.

It is preferred to use Na₂O and K₂O in combination in order to produce a crystallized glass substrate having a β-spodumene solid solution precipitated therein. The reason for this is as follows: when the meltability and the formability are to be enhanced without introducing K₂O, Na₂O needs to be introduced excessively, because Na₂O is a component that is trapped in the β-spodumene solid solution; and hence the glass is liable to be devitrified during forming. In order to suppress the devitrification during forming and lower the viscosity of the glass, it is preferred to use K₂O, which enhances the meltability and the formability without being trapped in the β-spodumene solid solution, in combination with Na₂O. When the total content of Na₂O and K₂O is large, the glass is liable to be devitrified during forming. In contrast, when the total content of Na₂O and K₂O is small, it is difficult to enhance the meltability and the formability. Therefore, the total content of Na₂O and K₂O is preferably from 0.05 to 5%, from 0.05 to 3%, or from 0.05 to 1%, particularly preferably from 0.35 to 0.9%.

TiO₂ is a component that increases the refractive index, and is also a component for crystal nucleation. When the content of TiO₂ is large, the glass is devitrified during forming, and is liable so be broken. Therefore, the content of TiO₂ is preferably from 0 to 10%, from 0 to 3.8%, or from 0.1 to 3.8%, particularly preferably from 0.5 to 3.6%.

As with TiO₂, ZrO₂ is a component that increases the refractive index, and is also a component for crystal nucleation. When the content of ZrO₂ is large, the glass is liable to be devitrified during melting, and it is difficult to form the crystallizable glass substrate. Therefore, the content of ZrO₂ is preferably from 0 to 5%, from 0 to 2.5%, or from 0.1 to 2.5%, particularly preferably from 0.5 to 2.3%.

When the total content of TiO₂ and ZrO₂ is small, the LAS-based crystal is hardly precipitated during crystallization of the crystallizable glass, and it is difficult to ensure a light scattering function. In contrast, when the total content of TiO₂ and ZrO₂ is large, the glass is devitrified during forming, and is liable to be broken. Therefore, the total content of TiO₂ and ZrO₂ is preferably from 1 to 15%, from 1 to 10%, from 1 to 7%, or from 2 to 6%, particularly preferably from 2.7 to 4.5%.

SnO₂ is a component that enhances fining property. When the content of SnO₂ is large, the glass is liable to be devitrified during melting, and it is difficult to form the crystallizable glass substrate. Therefore, the content of SnO₂ is preferably from 0 to 2%, from 0 to 1%, from 0 to 0.6%, or from 0 to 0.45%, particularly preferably from 0.01 to 0.4%.

Cl and SO₃ are each a component that enhances the fining property. The content of Cl is preferably from 0 to 2%. In addition, the content of SO₃ is preferably from 0 to 2%.

As₂O₃ and Sb₂O₃ are each a component that enhances the fining property. However, those components are components that present high environmental loads. In addition, those components are components that are reduced in a float bath to become metal, foreign matter, when forming is performed by a float method. Therefore, in the present invention, it is preferred that As₂O₃ and Sb₂O₃ be substantially prevented from being contained.

As a component that forms the skeleton of the glass, B₂O₃ may be introduced. However, when the content of B₂O₃ is large, heat resistance is liable to lower. Therefore, the content of B₂O₃ is preferably from 0 to 2%.

P₂O₅ is a component that suppresses the devitrification during forming, and promotes nucleation. The content of P₂O₅ is preferably from 0 to 5% or from 0 to 3%, particularly preferably from 0 to 2%.

CaO, SrO, and BaO are each a component that encourages the devitrification during melting. The total content of CaO, SrO, and BaO is preferably from 0 to 5% or from 0 to 2%.

NiO, CoO, Cr₂O₃, Fe₂O₃, V₂O₅, Nb₂O₃, and Gd₂O₃ are each a component that may be added as a coloring agent. The total content of those components is preferably from 0 to 2%.

Any component other than the above-mentioned components may be introduced at a content of, for example, up to 5%.

The crystallizable glass substrate (and the crystallized glass substrate) of the present invention each have a thickness of preferably 2.0 mm or less, 1.5 mm or less, 1.3 mm or less, 1.1 mm or less, 0.8 mm or less, 0.6 mm or less, 0.5 mm or less, 0.3 mm or less, or 0.2 mm or less, particularly preferably 0.1 mm or less. As the thickness is smaller, an OLED illumination device is reduced in weight more easily. However, when the thickness is extremely small, mechanical strength is liable to lower. Therefore, the thickness is preferably 10 μm or more, particularly preferably 30 μm or more.

The crystallizable glass substrate of the present invention has a refractive index nd of preferably more than 1.500, 1.580 or more, or 1.600 or more, particularly preferably 1.630 or more. When the refractive index nd is 1.500 or less, it is difficult to extract light to the outside owing to its reflection at the interface between a transparent conductive film and the crystallized glass substrate. In contrast, when the refractive index nd exceeds 2.3, it is difficult to extract light to the outside owing to a higher reflectance at the interface between air and the crystallized glass substrate. Therefore, the refractive index nd is preferably 2.3 or less, 2.2 or less, 2.1 or less, 2.0 or less, or 1.9 or less, particularly preferably 1.75 or less.

A manufacturing method for crystallized glass of the present invention is described. First, glass raw materials are blended to give a predetermined composition. The obtained glass batch is melted at a temperature of from 1,550 to 1,750° C., and then formed into a sheet shape. Thus, a crystallizable glass substrate is obtained. It should be noted that, as a forming method, there is given, for example, a float method, a roll out method, or a press method. In the case where the surface smoothness of the crystallizable glass substrate is to be enhanced, a float method is preferred. In the case where a large-size crystallizable glass substrate is to be produced, a roll out method is preferred. In the case where the devitrification is to be suppressed during forming, a press method is preferred.

Next, the crystallizable glass substrate is subjected to heat treatment at a temperature of from 800 to 1,100° C. for from 0.5 to 3 hours to grow a crystal. Thus, a crystallized glass substrate can be produced. It should be noted that, as required, a crystal nucleation step of forming a crystal nucleus in the crystallizable glass substrate may be performed prior to the step of growing a crystal.

It is particularly preferred that, in the heat treatment, the crystallizable glass substrate be maintained in a crystal growth temperature range for the crystallizable glass substrate for 30 minutes or more and be prevented from being maintained in a crystal nucleation temperature range for the crystallizable glass substrate for 30 minutes or more. With this, a crystal nucleus is prevented from being precipitated in a glass matrix in a large amount, and hence the average crystal grain size per crystal grain easily becomes large. As a result, a crystal grain easily becomes coarse to the extent that the light scattering function is exhibited in a visible light range.

In the crystallized glass substrate of the present invention, a LAS-based crystal is preferably precipitated as a main crystal. With this, the light scattering function can be ensured. In addition, the thermal expansion coefficient in a temperature range of from 30 to 750° C. ranges from −10×10⁻⁷ to 30×10⁻⁷/° C., and hence thermal shock resistance can be enhanced.

In order to precipitate a β-quartz solid solution as the LAS-based crystal, it is appropriate to perform heat treatment at a temperature of from 800 to 950° C. for from 0.5 to 3 hours after the crystal nucleation. In order to precipitate a β-spodumene solid solution as the LAS-based crystal, it is appropriate to perform heat treatment at a temperature of from 1,000 to 1,100° C. for from 0.5 to 3 hours after the crystal nucleation.

The crystallized glass substrate of the present invention has an average crystal grain size of preferably from 10 to 2,000 nm, from 20 to 1,800 nm, from 100 to 1,500 nm, or from 200 to 1,500 nm, particularly preferably from 400 to 1,000 nm. With this, the light scattering function is easily enhanced in a visible light range.

The crystallized glass substrate of the present invention has a haze value of preferably 0.2% or more, 1% or more, 10% or more, 20% or more, or 30% or more, particularly preferably from 50 to 95%. When the haze value is too small, a large amount of light is trapped in the crystallized glass substrate, and hence light extraction efficiency is liable to lower.

The crystallized glass substrate of the present invention has a total light transmittance of preferably 40% or more, 50% or more, or 60% or more. With this, brightness can be enhanced when an OLED element is assembled.

The crystallized glass substrate of the present invention has a value represented by (a radiation flux value to foe obtained from one surface of the crystallized glass substrate, when light is radiated from another surface of the crystallized glass substrate at an incident angle of 60°)/(a radiation flux value to be obtained from one surface of the crystallized glass substrate, when light is radiated from another surface of the crystallized glass substrate at an incident angle of 0°) of preferably 0.005 or more, 0.01 or more, 0.03 or more, 0.05 or more, or 0.08 or more, particularly preferably 0.1 or more. When the above-mentioned value is too small, a large amount of light is trapped in the crystallized glass substrate, and hence the light extraction efficiency is liable to lower.

Besides, a diffusion plate of the present invention is a crystallized glass substrate comprising as a composition at least Al₂O₃ and/or SiO₂. The total content of SiO₂ and Al₂O₃ is preferably 70 mass % or more, particularly preferably 75 mass % or more. With this, weather resistance can be enhanced.

In the diffusion plats of the present invention, the crystallized glass substrate has a crystallinity of from 10 to 90%, preferably from 40 to 85% or from 45 to 80%, particularly preferably from 50 to 75%. When the crystallinity is too low, it is difficult to ensure light scattering property. In contrast, when the crystallinity is too high, light transmitting property is liable to lower.

In the diffusion plate of the present invention, the crystallized glass substrate comprises as a main crystal preferably an Al—Si—O-based crystal, an R—Si—O-based crystal, an R—Al—O-based crystal, or an R—Al—Si—O-based crystal, particularly preferably an Al—Si—O-based crystal or an R—Al—Si—O-based crystal. The Al—Si—O-based crystal easily forms a needle-like crystal, and hence the area at the interface between matrix glass and the crystal becomes large even when the crystallinity is low. As a result, emitted light is easily scattered. In addition, the R—Al—Si—O-based crystal has a high density and a difference in refractive index between matrix glass and the crystal easily becomes large. Therefore, a reflectance at the interface between the matrix glass and the crystal is improved even when the crystallinity is low. As a result, emitted light is easily scattered.

In the case of allowing the Al—Si—O-based crystal to precipitate as a main crystal, the diffusion plate preferably comprises as a composition, in terms of mass %, 45 to 75% of SiO₂, 13 to 30% of Al₂O₃, and 0 to 30% of Li₂O+Na₂+K₂O+MgO+CaO+SrO+BaO+ZnO.

SiO₂ is a component than forms she skeleton of glass and serves as a constituent of the Al—Si—O-based crystal. The content of SiO₂ is preferably from 45 to 75% or from 50 to 70%, particularly preferably from 53 to 65%. When the content of SiO₂ is too small, the weather resistance is liable to lower. In contrast, when the content of SiO₂ is too large, it is difficult to perform vitrification.

Al₂O₃ is a component that forms the skeleton of the glass and serves as a constituent of the Al—Si—O-based crystal. The content of Al₂O₃ is preferably from 13 to 30% or from 15 to 27%, particularly preferably from 17 to 25%. When the content of Al₂O₃ is too small, the weather resistance is liable to lower. In contrast, when the content of Al₂O₃ is too large, it is difficult to perform vitrification.

Li₂O+Na₂O+K₂O+MgO+CaO+SrO+BaO+ZnO are components that enhance meltability and formability. The total content of Li₂O+Na₂O+K₂O+MgO+CaO+SrO+BaO+ZnO is preferably from 0 to 30%, from 1 to 25%, or from 5 to 23%, particularly preferably from 8 to 20%. When the total content of Li₂O+Na₂O+K₂O+MgO+CaO+SrO+BaO+ZnO is too small, the meltability and the formability are liable to lower. In contrast, when the total content of Li₂O+Na₂O+K₂O+MgO+CaO+SrO+BaO+ZnO is too large, the weather resistance is liable to lower. It should be noted that the content of Li₂O is preferably from 0 to 5%, particularly preferably from 0 to 1%. The content of Na₂O is preferably from 0 to 10%, particularly preferably from 0.5 to 6%. The content of K₂O is preferably from 0 to 10%, particularly preferably from 1 to 6%. The content of MgO is preferably from 0 to 6%, particularly preferably from 0.1 to 1%. The content of CaO is preferably from 0 to 6%, particularly preferably from 0.1 to 1%. The content of SrO is preferably from 0 to 6%, particularly preferably from 0.1 to 3%. The content of BaO is preferably from 0 to 10% or from 1 to 9%, particularly preferably from 2 to 7%. The content of ZnO is preferably from 0 to 8%, particularly preferably from 0.1 to 7%.

The molar ratio Al₂O₃/(Li₂O+Na₂O+K₂O+MgO+CaO+SrO+BaO+ZnO) is preferably 1.3 or more, particularly preferably 1.4 or more. When the molar ratio Al₂O₃/(Li₂O+Na₂O+K₂O+MgO+CaO+SrO+BaO+ZnO) is too small, the Al—Si—O-based crystal is hardly precipitated during heat treatment.

For example, the following components may be introduced in addition to the above-mentioned components.

TiO₂ is a component that enhances the weather resistance and is also a component that functions as a crystal nucleus. The content of TiO₂ is preferably from 0 to 7% or from 0 to 5%, particularly preferably from 0.01 to 3%. When the content of TiO₂ is too large, the glass is liable to be devitrified during forming.

ZrO₂ as a component that enhances the weather resistance and is also a component that functions as a crystal nucleus. The content of ZrO₂ is preferably from 0 to 7% or from 0 to 5%, particularly preferably from 0.1 to 4%. When the content of ZrO₂ is too large, the glass is liable to be devitrified during forming.

B₂O₃ is a component that forms the skeleton of the glass. The content of B₂O₃ is preferably from 0 to 10%, particularly preferably from 0 to 7%. When the content of B₂O₃ is too large, the weather resistance is liable to lower. Besides, the Al—Si—O-based crystal is hardly precipitated during heat treatment.

P₂O₅ is a component that forms the skeleton of the glass. The content of P₂O₅ is preferably from 0 to 5%, particularly preferably from 0.1 to 3%. When the content of P₂O₅ is too large, the weather resistance is liable to lower. Besides, the Al—Si—O-based crystal is hardly precipitated during heat treatment.

The content of a transition metal oxide is preferably 1% or less, particularly preferably 0.1% or less, because the transition metal oxide is colored.

As₂O₃, Sb₂O₃, SnO₂, SO₃, Cl, and the like may be introduced as fining agents at a total content of up to 3%.

In the case of precipitating the Al—Si—O-based crystal as a main crystal, the crystallizable glass substrate is preferably maintained in a temperature range of from 850 to 1,100° C. for from 10 to 60 minutes to be crystallized. As required, there may be performed a step of precipitating a crystal nucleus, involving maintaining the crystallizable glass substrate in a temperature range of from 650 to 800° C. for from about 10 to about 100 minutes, prior to the crystallization step.

In the case of allowing the R—Al—Si—O-based crystal to precipitate as a main crystal, the diffusion plate preferably comprises as a composition, in terms of mass %, 45 to 70% of SiO₂, 13 to 30% of Al₂O₃, and 1 to 35% of Li₂O+Na₂O+K₂O+MgO+CaO+SrO+BaO+ZnO.

SiO₂ is a component that forms the skeleton of glass and serves as a constituent of the R—Al—Si—O-based crystal. The content of SiO₂ is preferably from 45 to 70% or from 50 to 68%, particularly preferably from 53 to 65%, when the content of SiO₂is too small, the weather resistance is liable to lower. In contrast, when the content of SiO₂ is too large, it is difficult to perform vitrification.

Al₂O₃ is a component that forms the skeleton of the glass and serves as a constituent of the R—Al—Si—O-based crystal. The content of Al₂O₃ is preferably from 13 to 30% or from 15 to 27%, particularly preferably from 17 to 25%. When the content of Al₂O₃ is too small, the weather resistance is liable to lower. In contrast, when the content of Al₂O₃ is too large, it is difficult to perform vitrification.

Li₂O+Na₂O+K₂O+MgO+CaO+SrO+BaO+ZnO are components that serve as constituents of the R—Al—Si—O-based crystal and enhance meltability and formability. The total content of Li₂O+Na₂O+K₂O+MgO+CaO+SrO+BaO+ZnO is preferably from 1 to 35%, from 2 to 25%, or from 5 to 23%, particularly preferably from 3 to 20%. When the total content of Li₂O+Na₂O+K₂O+MgO+CaO+SrO+BaO+ZnO is too small, the meltability and the formability are liable to lower. In contrast, when the total content of Li₂O+Na₂O+K₂O+MgO+CaO+SrO+BaO+ZnO is too large, the weather resistance is liable to lower. It should be noted that the content of Li₂O is preferably from 0 to 5%, particularly preferably from 0 to 1%. The content of Na₂O is preferably from 0 to 10%, particularly preferably from 0.5 to 6%. The content of K₂O is preferably from 0 to 10%, particularly preferably from 1 to 6%. The content of MgO is preferably from 0 to 6%, particularly preferably from 0.1 to 1%. The content of CaO is preferably from 0 to 6%, particularly preferably from 0.1 to 1%. The content of SrO is preferably from 0 to 6%, particularly preferably from 0.1 to 3%. The content of BaO is preferably from 0 to 10% or from 1 to 9%, particularly preferably from 2 to 7%. The content of ZnO is preferably from 0 to 11% or from 1 to 10%, particularly preferably from 2 to 9%.

The molar ratio Al₂O₃/(Li₂O+Na₂O+K₂O+MgO+CaO+SrO+BaO+ZnO) is preferably 1.3 or less, particularly preferably 1.25 or less. When the molar ratio Al₂O₃/(Li₂O+Na₂O+K₂O+MgO+CaO+SrO+BaO+ZnO) is too small, the R—Al—Si—O-based crystal is hardly precipitated during heat treatment.

For example, the following components may be introduced in addition to the above-mentioned components.

TiO₂ is a component that enhances the weather resistance and is also a component that functions as a crystal nucleus. The content of TiO₂ is preferably from 0 to 7% or from 0 to 5%, particularly preferably from 0.01 to 3%. When the content of TiO₂ is too large, the glass is liable to be devitrified during forming.

ZrO₂ is a component that enhances the weather resistance and is also a component that functions as a crystal nucleus. The content of ZrO₂ is preferably from 0 to 7% or from 0 to 5%, particularly preferably from 0.1 to 4%. When the content of ZrO₂ is too large, the glass is liable to be devitrified during forming.

B₂O₃ is a component that forms the skeleton of the glass. The content of B₂O₃ is preferably from 0 to 10%, particularly preferably from 0 to 7%. When the content of B₂O₃ is too large, the weather resistance is liable to lower. Besides, the R—Al—Si—O-based crystal is hardly precipitated during heat treatment.

P₂O₅ is a component that forms the skeleton of the glass. The content of P₂O₅ is preferably from 0 to 5%, particularly preferably from 0.1 to 3%. When the content of P₂O₅ is too large, the weather resistance is liable to lower. Besides, the R—Al—Si—O-based crystal is hardly precipitated during heat treatment.

The content of a transition metal oxide is preferably 1% or less, particularly preferably 0.1% or less, because the transition metal oxide is colored.

As₂O₃, Sb₂O₃, SnO₂, SO₃, Cl, and the like may be introduced as fining agents at a total content of up to 3%.

In the case of precipitating the R—Al—Si—O-based crystal as a main crystal, the crystallizable glass substrate is preferably maintained in a temperature range of from 850 to 1,100° C. for from 10 to 60 minutes to be crystallized. As required, there may be performed a step of precipitating a crystal nucleus, involving maintaining the crystallizable glass substrate in a temperature range of from 650 to 800° C. for from about 10 to about 100 minutes, prior to the crystallization step.

A crystal grain size may be controlled by adjusting the temperature and time period of the heat treatment. In particular, when a crystal nucleus is preliminarily formed prior to the crystallization, the crystal grain size is easily controlled. As the number of the crystal nuclei is larger, the crystal grain size can be more reduced.

The diffusion plate of the present invention preferably has an average crystal grain size of a main crystal of from 20 to 30,000 nm. When the average crystal grain size of the main crystal is too small, the light scattering property is liable to be insufficient. In contrast, a main crystal having an excessively large average crystal grain size is liable to cause breakage during growth of a crystal.

The diffusion plate of the present invention has a haze value of preferably 10% or more, 20% or more, 30% or more, or 40% or more, particularly preferably from 50 to 99%. With this, the light scattering property is improved, and the light extraction efficiency of an illumination device can be enhanced.

The diffusion plate of the present invention may be produced by various methods. For example, the diffusion plate may be produced as described below.

First, grass raw materials are blended to give a predetermined composition, and then melted uniformly. Next, the molten glass is formed into a sheet shape by various forming methods. As the forming method, a roll out method, a float method, a down-draw method (for example, a slot down-draw method or an overflow down-draw method), a press method, or the like may be adopted. It should be noted that plate bending processing or the like may be performed on the glass sheet after the forming to form a concave surface, a convex surface, or a wave surface on one surface of the glass sheet.

Next, the glass substrate is cut into an appropriate size as required, and then subjected to heat treatment to be crystallized. The heat treatment conditions are determined in consideration of viscosity characteristics such as a softening point, and a crystal growth rate.

Finally, the crystallized glass substrate is subjected to surface polishing, cutting, or drilling processing as required. Thus, a diffusion plate can be produced.

The diffusion plate thus produced may be applied to an illumination device, in particular an OLED illumination device. It should be noted that the diffusion plate of the present invention may also be applied to an application of diffusing light from an LED, which is a point light source.

In the case where the diffusion plate of the present invention is used for an OLED illumination device, for example, the diffusion plate is preferably used as an alternative to a glass sheet 11 illustrated in FIG. 3. The diffusion plate of the present invention may be bonded onto the outer surface of the glass sheet 11.

### EXAMPLES

### Example 1

The present invention relating to the above-mentioned crystallizable glass and crystallized glass is hereinafter described in detail by way of Example 1. It should be noted that Example 1 described below is merely illustrative. The present invention is by no means limited to Example 1 described below.

Tables 1 to 4 show Example 1 (samples Nos. 1 to 23) of the present invention.

TABLE 1

| | No. 1 | No. 2 | No. 3 | No. 4 | No. 5 | No. 6 |
|---|---|---|---|---|---|---|
| Glass | | | | | | |
| composition | | | | | | |
| (mass %) | | | | | | |
| SiO₂ | 67.8 | 66.7 | 67.9 | 67.55 | 67.75 | 65.1 |
| Al₂O₃ | 23.0 | 22.9 | 22.1 | 22.1 | 22.1 | 22.0 |
| Li₂O | 2.5 | 3.8 | 3.5 | 3.4 | 3.5 | 4.4 |
| MgO | 1.0 | 0.1 | 0.3 | 0.5 | 0.4 | 1.0 |
| ZnO | 1.3 | 1.2 | 1.0 | 1.0 | 0.9 | — |
| Na₂O | — | 0.3 | 0.1 | 0.1 | 0.1 | 0.4 |
| K₂O | 0.7 | 0.5 | 0.6 | 0.6 | 0.6 | 0.3 |
| CaO | — | — | — | — | — | — |
| BaO | — | — | — | — | — | 1.2 |
| TiO₂ | 1.4 | 1.2 | 1.5 | 1.5 | 1.6 | 2.0 |
| ZrO₂ | 2.3 | 1.3 | 1.8 | 1.9 | 1.6 | 2.2 |
| P₂O₅ | — | 1.7 | 1.0 | 1.2 | 1.2 | 1.4 |
| B₂O₃ | — | — | — | — | — | — |
| SnO₂ | — | 0.3 | 0.2 | 0.15 | 0.25 | — |
| Heat treatment | | | | | | |
| conditions (1) | | | | | | |
| Main crystal | β-Q | β-Q | β-Q | β-Q | β-Q | β-Q |
| Heat treatment | | | | | | |
| conditions (2) | | | | | | |
| Main crystal | β-S | β-S | β-S | β-S | β-S | β-S |
| Heat treatment | | | | | | |
| conditions (3) | | | | | | |
| Main crystal | β-Q | β-Q | β-Q | β-Q | β-Q | β-Q |

TABLE 2

| | No. 7 | No. 8 | No. 9 | No. 10 | No. 11 | No. 12 |
|---|---|---|---|---|---|---|
| Glass | | | | | | |
| composition | | | | | | |
| (mass %) | | | | | | |
| SiO₂ | 65.8 | 67.6 | 68.5 | 67.0 | 67.8 | 66.7 |
| Al₂O₃ | 22.0 | 22.0 | 20.0 | 21.2 | 23.0 | 22.5 |
| Li₂O | 4.4 | 3.7 | 4.0 | 4.0 | 2.5 | 3.3 |
| MgO | 0.7 | 0.5 | 0.7 | 0.5 | 1.0 | 0.6 |
| ZnO | — | 0.5 | 0.7 | 0.7 | 1.3 | 0.8 |
| Na₂O | 0.4 | 0.2 | 0.8 | 0.6 | 0.1 | 0.6 |
| K₂O | 0.4 | 0.6 | — | 0.2 | 0.6 | 0.1 |
| CaO | — | — | — | — | — | — |
| BaO | 1.5 | — | — | 1.0 | — | — |
| TiO₂ | 1.5 | 1.7 | 1.9 | 1.8 | 1.4 | 1.6 |
| ZrO₂ | 2.2 | 1.8 | 1.9 | 1.9 | 2.3 | 2.0 |
| P₂O₅ | 1.0 | 1.0 | 1.0 | 0.5 | — | 0.7 |
| B₂O₃ | — | — | — | — | — | 1.0 |
| SnO₂ | 0.1 | 0.4 | 0.5 | 0.6 | — | 0.1 |
| Heat treatment | | | | | | |
| conditions (1) | | | | | | |
| Main crystal | β-Q | β-Q | β-Q | β-Q | β-Q | β-Q |
| Heat treatment | | | | | | |
| conditions (2) | | | | | | |
| Main crystal | β-S | β-S | β-S | β-S | β-S | β-S |
| Heat treatment | | | | | | |
| conditions (3) | | | | | | |
| Main crystal | β-Q | β-Q | β-Q | β-Q | β-Q | β-Q |

TABLE 3

| | No. 13 | No. 14 | No. 15 | No. 16 | No. 17 | No. 18 |
|---|---|---|---|---|---|---|
| Glass | | | | | | |
| composition | | | | | | |
| (mass %) | | | | | | |
| SiO₂ | 65.6 | 66.1 | 68.0 | 66.1 | 67.0 | 65.6 |
| Al₂O₃ | 22.0 | 22.5 | 22.0 | 22.6 | 23.0 | 22.0 |
| Li₂O | 4.4 | 3.9 | 4.0 | 3.6 | 4.0 | 4.4 |
| MgO | 1.0 | 1.0 | 1.0 | 0.8 | — | 0.7 |
| ZnO | — | — | 0.5 | 0.5 | 0.5 | — |
| Na₂O | 0.4 | 0.4 | 0.5 | 0.2 | 0.5 | 0.4 |
| K₂O | 0.4 | 0.4 | 0.5 | 0.5 | 0.5 | 0.4 |
| CaO | — | — | — | — | — | — |
| BaO | 1.5 | 1.2 | — | 1.2 | 1.0 | 1.5 |
| TiO₂ | 1.5 | 1.5 | 3.5 | 1.3 | 2.1 | 1.5 |
| ZrO₂ | 2.2 | 2.1 | — | 2.0 | 0.9 | 2.2 |
| P₂O₅ | 1.0 | 0.9 | — | 1.2 | 0.5 | 1.0 |
| B₂O₃ | — | — | — | — | 0.5 | — |
| SnO₂ | — | — | — | — | — | 0.3 |
| Heat treatment | | | | | | |
| conditions (1) | | | | | | |
| Main crystal | β-Q | β-Q | β-Q | β-Q | β-Q | β-Q |
| Heat treatment | | | | | | |
| conditions (2) | | | | | | |
| Main crystal | β-S | β-S | β-S | β-S | β-S | β-S |
| Heat treatment | | | | | | |
| conditions (3) | | | | | | |
| Main crystal | β-Q | β-Q | β-Q | β-Q | β-Q | β-Q |

TABLE 4

| | No. 19 | No. 20 | No. 21 | No. 22 | No. 23 |
|---|---|---|---|---|---|
| Glass composition | | | | | |
| (mass %) | | | | | |
| SiO₂ | 66.5 | 65.3 | 66.0 | 66.1 | 65.6 |
| Al₂O₃ | 22.2 | 22.5 | 22.4 | 22.9 | 22.2 |
| Li₂O | 3.8 | 3.9 | 4.4 | 4.1 | 3.7 |
| MgO | 0.9 | 1.0 | 0.8 | 0.55 | 0.7 |
| ZnO | — | — | — | — | — |
| Na₂O | 0.7 | 0.5 | 0.5 | 0.4 | 0.4 |
| K₂O | — | 0.3 | 0.5 | 0.3 | 0.3 |
| CaO | 0.5 | — | 0.6 | — | — |
| BaO | 1.0 | 1.2 | 1.5 | — | 1.2 |
| TiO₂ | 2.3 | 1.6 | 1.1 | 2.1 | 2.0 |
| ZrO₂ | 1.9 | 2.1 | 1.0 | 2.05 | 2.2 |
| P₂O₅ | 1.0 | 0.9 | 1.2 | 1.35 | 1.4 |
| B₂O₃ | — | — | — | — | — |
| SnO₂ | — | 0.7 | — | 0.15 | 0.3 |
| Heat treatment | β-Q | β-Q | β-Q | β-Q | β-Q |
| conditions (1) | | | | | |
| Main crystal | | | | | |
| Heat treatment | β-S | β-S | β-S | β-S | β-S |
| conditions (2) | | | | | |
| Main crystal | | | | | |
| Heat treatment | β-Q | β-Q | β-Q | β-Q | β-Q |
| conditions (3) | | | | | |
| Main crystal | | | | | |

Each of the samples was prepared as described below. First, raw materials were blended to give a glass composition shown in Table 1, and mixed uniformly. Then, the mixture was placed in a platinum crucible, and melted at 1,600° C. for 20 hours. Next, the molten glass was allowed to flow out onto a carbon surface plate, and formed into a thickness of 5 mm with a roller. The resultant was cooled from 700° C. to room temperature at a temperature dropping rate of 100° C./hr with an annealing furnace, to produce a crystallizable glass.

Next, the crystallizable glass was subjected to heat treatment under each of the heat treatment conditions (1) to (3) described below, to produce a crystallized glass. It should be noted that the temperature elevating rate from room temperature to a crystal nucleation temperature was set to 300° C./hr, the temperature elevating rate from the crystal nucleation temperature to a crystal growth temperature was set to 150° C./hr, and the temperature dropping rate from the crystal growth temperature to room temperature was set to 100° C./hr.

Heat treatment conditions (1) nucleation: 2 hours at 780° C.→crystal growth: 1 hour at 900° C.

Heat treatment conditions (2) nucleation: 2 hours at 780° C.→crystal growth: 1 hour at 1,160° C.
Heat treatment conditions (3) nucleation: without retention→crystal growth; 1 hour at 900° C.

The crystallized glasses were each evaluated for its main crystal with an X-ray diffractometer (RINT-2100 manufactured by Rigaku Corporation). It should be noted that the measurement range was set to 2θ=10 to 60°. It should be noted that, in Tables 1 to 4, the “β-Q” refers to a β-quartz solid, solution and the “β-S” refers to a β-spodumene solid solution.

Tables 1 to 4 revealed that crystallized glasses each having as a main crystal a β-quartz solid solution precipitated therein were able to be obtained under the heat treatment conditions (1) or (3). Further, crystallized glasses each having as a main crystal a β-spodumene solid solution precipitated therein were able to be obtained under the heat treatment conditions (2).

### Evaluation of Light Scattering Function

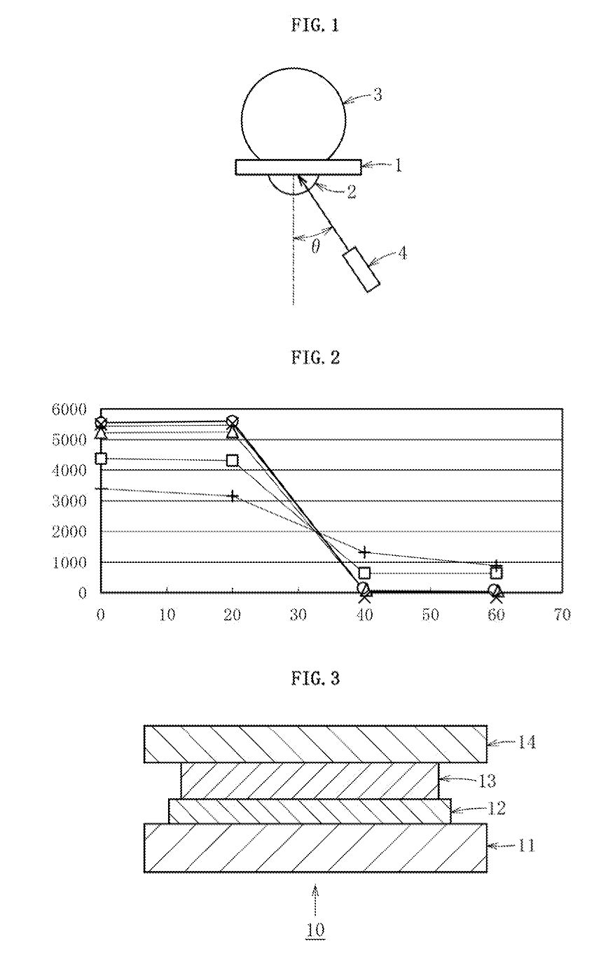

Next, the sample No. 23 before the heat treatment was subjected to heat treatment under each of the heat treatment conditions (A) to (C) described below. The sample was evaluated for its light scattering function with a measuring device illustrated in FIG. 1.

(A) The sample is loaded in an annealing furnace with a furnace temperature kept at 900° C., retained for 1 hour, and then taken out from the furnace, followed by being allowed to stand still at room temperature.

(B) The sample is loaded in an annealing furnace with a furnace temperature kept at 940° C., retained for 1 hour, and then taken out from the furnace, followed by being allowed to stand still at room temperature.

(C) The sample is loaded in an electric furnace, and the temperature is elevated from room temperature to 760° C. at a rate of 20° C./min, kept at 760° C. for 1 minute, elevated therefrom to 940° C. at a rate of 20° C./min, and kept at 940° C. for 1 hour, and then the sample is taken out from the furnace, followed by being allowed to stand still at room temperature.

SS-1 manufactured by Nippon Electric Glass Co., Ltd. was evaluated for its light scattering function in the same manner as described above. The results are shown in Table 5. It should be noted that each of the evaluation samples had a thickness of 1.1 mm.

The evaluation method for the light scattering function is described in detail. First, an immersion liquid was used to provide a hemispherical lens having a refractive index nd of 1.74on one surface of a substrate, and light from a light source was allowed to enter toward the center of the hemispherical lens. Next, light passed through the inside of the substrate and extracted from another surface of the substrate was detected with an integrating sphere. Further, a similar experiment was repeated while the incident angle θ was changed, and extracted light was detected with the integrating sphere at respective incident angles. The results are shown in Table 5. Herein, a red laser SNF-660-S manufactured by MORITEX Corporation was used as the light source, a fiber multi-channel spectrometer USB4000 manufactured by Ocean Photonics was used as a spectrometer, and OPWave manufactured by Ocean Photonics was used as software. In addition, P50-2-UV-VIS manufactured by Ocean Optics, Inc. was used as an optical fiber for connecting the integrating sphere to the spectrometer.

FIG. 1 is a schematic sectional view illustrating the evaluation method for the light scattering function. As is apparent from FIG. 1, a hemispherical lens 2 is arranged on one surface of a substrate 1, and an integrating sphere 3 is arranged on another surface of the substrate 1. The gradient from a surface perpendicular to the surface of the substrate 1 is defined as θ. Light is output from a light source 4 at the angle toward the center of the hemispherical lens 2, and detected with the integrating sphere 3 after passing through the inside of the substrate 1.

TABLE 5

| | | | No. 23 | No. 23 | No. 23 | |
|---|---|---|---|---|---|---|
| | | No. 23 | Heat | Heat | Heat | |
| | | No heat | treatment | treatment | treatment | |
| | | treatment | (A) | (B) | (C) | SS-1 |
| Radi- | 0° | 5,552 | 4,355 | 3,391 | 5,431 | 5,224 |
| ation | 20° | 5,583 | 4,310 | 3,148 | 5,436 | 5,255 |
| flux | 40° | 33 | 626 | 1,331 | 49 | 76 |
| value | 60° | 33 | 625 | 885 | 79 | 16 |
| (μW) | 60°/ | 0.006 | 0.143 | 0.261 | 0.015 | 0.003 |
| | 0° | | | | | |

| | | | | | |
|---|---|---|---|---|---|
| Haze value | 0.16 | 31.07 | 80.8 | 1.06 | — |
| (%) | | | | | |
| Total light | 91.6 | 75.1 | 67.0 | 87.6 | — |
| transmittance | | | | | |
| (%) | | | | | |

FIG. 2 is a chart in which the data in Table 5 are plotted. In FIG. 2, the vertical axis represents a radiation flux value (μW), and the horizontal axis represents an incident angle θ (°). Symbol “∘” represents data on the sample No. 23 before the heat treatment, Symbol “□” represents data on the sample No. 23 after the heat treatment under the heat treatment conditions (A), Symbol “+” represents data on the sample No. 23 after the heat treatment under the heat treatment conditions (B), Symbol “×” represents data on the sample No. 23 after the heat treatment under the heat treatment conditions (C), and Symbol “Δ” represents data on SS-1.

The haze value and the total light transmittance were values measured by using as an evaluation sample the sample (thickness: 1.1 mm) having both surfaces mirror polished, with a TM double beam type automatic haze computer manufactured by Suga Test Instruments Co., Ltd.

Table 5 revealed that, when the sample No. 23 was subjected to heat treatment under each of the heat treatment conditions (A) to (C), high radiation flex values were obtained even at an incident angle of 40° or more, which was close to the critical angle. It should be noted that a β-quartz solid solution was precipitated as a main crystal under each of the heat treatment conditions (A) to (C). In contrast, SS-1 manufactured by Nippon Electric Glass Co., Ltd. had a low radiation flux value at an incident angle of 40° or more.

### Example 2

The present invention relating to the above-mentioned diffusion plate and illumination device using the diffusion plate is hereinafter described in detail by way of Example 2. It should be noted that Example 2 described below is merely illustrative. The present invention is by no means limited to Example 2 described below.

Table 6 shows compositions of crystallized glass substrates (glass sheets).

| | Sample A | Sample B | Sample C | Sample D | Sample E |
|---|---|---|---|---|---|
| SiO₂ (wt %) | 58.7 | 61.6 | 57.2 | 58.7 | 59.3 |
| Al₂O₃ | 22.8 | 20.3 | 21.4 | 16.8 | 20.4 |
| B₂O₃ | — | 3.0 | 4.9 | — | — |
| Li₂O | — | — | — | — | 0.4 |
| Na₂O | 4.3 | 2.6 | 3.0 | 0.9 | 2.6 |
| K₂O | 4.6 | 4.0 | 4.1 | 3.2 | 3.0 |
| CaO | — | 0.6 | — | — | — |
| SrO | — | 1.2 | 1.3 | 2.1 | — |
| BaO | 4.3 | 4.4 | 4.3 | 5.3 | 6.4 |
| ZnO | 0.6 | 0.6 | 0.6 | 6.7 | 1.1 |
| P₂O₅ | 3.0 | — | — | 2.9 | 3.9 |
| TiO₂ | — | — | 0.6 | — | — |
| ZrO₂ | 1.7 | 1.8 | 2.6 | 3.4 | 2.9 |
| R Total content | 13.8 | 13.4 | 13.3 | 18.2 | 13.5 |
| SiO₂ (mol %) | 70.0 | 72.0 | 68.0 | 71.0 | 71.5 |
| Al₂O₃ | 16.0 | 14.0 | 15.0 | 12.0 | 14.5 |
| B₂O₃ | — | 3.0 | 5.0 | — | — |
| Li₂O | — | — | — | — | 1.0 |
| Na₂O | 5.0 | 3.0 | 3.5 | 1.0 | 3.0 |
| K₂O | 3.5 | 3.0 | 3.1 | 2.5 | 2.3 |
| CaO | — | 0.7 | — | — | — |
| SrO | — | 0.8 | 0.9 | 1.5 | — |
| BaO | 2.0 | 2.0 | 2.0 | 2.5 | 3.0 |
| ZnO | 0.5 | 0.5 | 0.5 | 6.0 | 1.0 |
| P₂O₅ | 1.5 | — | — | 1.5 | 2.0 |
| TiO₂ | — | — | 0.5 | — | — |
| ZrO₂ | 1.0 | 1.0 | 1.5 | 2.0 | 1.7 |
| R Total content | 11.0 | 10.0 | 10.0 | 13.5 | 10.3 |

Raw materials were blended to give a composition shown in Table 6, melted in a melting crucible at a temperature of from 1,200 to 1,700° C. for from 4 to 24 hours, and then allowed to flow out onto a carbon plate to be formed into a sheet shape. Then, the resultant was subjected to annealing, to produce glass samples (samples A to E).

Next, the glass samples were each subjected to heat treatment under the heat treatment conditions shown in Table 7 in an electric furnace, to provide crystallized glass substrates (samples Nos. 24 to 29). The procedure is specifically described with taking the sample No. 24 as an example. First, the sample A was loaded in an electric furnace set to 500° C. The temperature was elevated to 780° C. at a temperature elevating rate of 600° C./hr, kept at 780° C. for 1 hour, further elevated from 780° C. to 900° C. at a temperature elevating rate of 600° C./hr, kept at 900° C. for 1 hour, and finally dropped from 900° C. to 25° C. at a temperature dropping rate of 100° C./hr. Then, the sample A was taken out from the electric furnace. It should be noted that a sample No. 30 is the sample A before the heat treatment.

TABLE 7

| | | | | | | | | | | | | | Comparative |
|---|---|---|---|---|---|---|---|---|---|---|---|---|---|
| | Example 2 | | | | | | | | | | | | Example |
| | No. 24 | | No. 25 | | No. 26 | | No. 27 | | No. 28 | | No. 29 | | No. 30 |
| Glass sample | A | | A | | B | | C | | D | | E | | A |
| Heat treatment | | | | | | | | | | | | | |
| conditions | | | | | | | | | | | | | |
| Start temperature | 500° | C. | 500° | C. | 500° | C. | 500° | C. | 500° | C. | 500° | C. | — |
| Temperature | 600° | C./hr | 900° | C./hr | 600° | C./hr | 900° | C./hr | 600° | C./hr | 900° | C./hr | — |
| elevating rate (1) | | | | | | | | | | | | | |
| Reached | 780° | C. | 780° | C. | 780° | C. | 780° | C. | 780° | C. | 780° | C. | — |
| temperature (1) | | | | | | | | | | | | | |
| Retention time | 1 | hr | 1 | hr | 2 | hr | 1 | hr | 30 | min | 1 | hr | — |
| period (1) | | | | | | | | | | | | | |
| Temperature | 600° | C./hr | 600° | C./hr | 600° | C./hr | 600° | C./hr | 600° | C./hr | 600° | C./hr | — |
| elevating rate (2) | | | | | | | | | | | | | |
| Reached | 900° | C. | 980° | C. | 920° | C. | 900° | C. | 1,000° | C. | 950° | C. | — |
| temperature (2) | | | | | | | | | | | | | |
| Retention time | 1 | hr | 1 | hr | 30 | min | 1 | hr | 1 | hr | 15 | min | — |
| period (2) | | | | | | | | | | | | | |
| Temperature | 100° | C./hr | 100° | C./hr | 100° | C./hr | 100° | C./hr | 100° | C./hr | 100° | C./hr | — |
| dropping rate (1) | | | | | | | | | | | | | |
| Reached | 25° | C. | 25° | C. | 25° | C. | 25° | C. | 25° | C. | 25° | C. | — |
| temperature (3) | | | | | | | | | | | | | |

| | | | | | | | |
|---|---|---|---|---|---|---|---|
| Main crystal | Al—Si—O— | Al—Si—O— | Al—Si—O— | Al—Si—O— | R—Al—Si—O— | Al—Si—O— | — |
| species | based | based | based | based | based | based | |
| Crystallinity (%) | 60 | 70 | 50 | 60 | 70 | 55 | 0 |
| Haze value (%) | 50 | 70 | 30 | 90 | 95 | 40 | 0.2 |

The main crystal species and the crystallinity were evaluated by XRD measurement after partly pulverizing each of the samples. It should be noted that, in the measurement, the measurement range was set to from 10 to 60° and the scan speed was set to 4°/min. It should be noted that the crystallinity was determined based on the expression [area of peak]×100/[area of peak+area of halo] (%) after calculating the area of a halo corresponding to the mass of an amorphous portion and the area of a peak corresponding to the mass of a crystal.

The haze value was measured by using as an evaluation sample the sample (thickness: 1 mm) having both surfaces mirror polished, with a TM double beam type automatic haze computer manufactured by Suga Test Instruments Co., Ltd.

Table 7 revealed that the samples Nos. 24 to 29 each had a high haze value, and hence had satisfactory light scattering property. Therefore, when the samples Nos. 24 to 29 are each used as a diffusion plate, the light extraction efficiency of an illumination device is believed to be able to be enhanced. In contrast, the sample No. 30 had a low haze value, and hence had poor light scattering property.

### INDUSTRIAL APPLICABILITY

The diffusion plate of the present invention is suitably applied to an OLED illumination device, and may also be applied to an LED illumination device, a mercury lamp, or a fluorescent lamp.

### REFERENCE SIGNS LIST

1 substrate (crystallized glass substrate)

2 hemispherical lens

3 integrating sphere

4 laser

10 OLED illumination device

11 glass sheet

12 anode

13 OLED layer

14 cathode

1-24. (canceled)

25. A crystallizable glass substrate, which is used for an OLED illumination device.

26. The crystallizable glass substrate according to claim 25, comprising as a glass composition, in terms of mass %, 40 to 80% of SiO₂, 10 to 35% of Al₂O₃, and 1 to 10% of Li₂O.

27. The crystallizable glass substrate according to claim 25, comprising as a glass composition, in terms of mass %, 55 to 73% of SiO₂, 17 to 27% of Al₂O₃, 2 to 5% of Li₂O, 0 to 1.5% of MgO, 0 to 1.5% of ZnO, 0 to 1% of Na₂O, 0 to 1% of K₂O, 0 to 3.8% of TiO₂, 0 to 2.5% of ZrO₂, and 0 to 0.6% of SnO₂.

28. The crystallizable glass substrate according to claim 26, wherein the crystallizable glass substrate is substantially free of As₂O₃ and Sb₂O₃.

29. The crystallizable glass substrate according to claim 25, wherein the crystallizable glass substrate has a thickness of 2.0 mm or less.

30. The crystallizable glass substrate according to claim 25, wherein the crystallizable glass substrate has a refractive index nd of more than 1.500.

31. A crystallized glass substrate, which is obtained by subjecting a crystallizable glass substrate to heat treatment,
the crystallizable glass substrate comprising the crystallizable glass substrate according to claim 25.

32. The crystallized glass substrate according to claim 31, comprising as a main crystal a β-quartz solid solution or a β-spodumene solid solution.

33. The crystallized glass substrate according to claim 31, wherein the crystallized glass substrate has an average crystal grain size of from 10 to 2,000 nm.

34. The crystallized glass substrate according to claim 31, wherein the crystallized glass substrate has a haze value of 0.2% or more.

35. The crystallized glass substrate according to claim 31, wherein the crystallized glass substrate has a value represented by (a radiation flux value to be obtained from one surface of the crystallized glass substrate, when light is radiated from another surface of the crystallized glass substrate at an incident angle of 60°)/(a radiation flux value to be obtained from one surface of the crystallized glass substrate, when light is radiated from another surface of the crystallized glass substrate at an incident angle of 0°) of 0.005 or more.

36. A manufacturing method for a crystallized glass substrate, the method comprising subjecting the crystallizable glass substrate according to claim 25 to heat treatment, to obtain a crystallized glass substrate,
in the heat treatment, the crystallizable glass substrate being maintained in a crystal growth temperature range for the crystallizable glass substrate for 30 minutes or more and being prevented from being maintained in a crystal nucleation temperature range for the crystallizable glass substrate for 30 minutes or more.

37. A diffusion plate, comprising a crystallized glass substrate obtained by subjecting the crystallizable glass substrate according to claim 25 to heat treatment,
the crystallized glass substrate comprising as a composition at least Al₂O₃ and/or SiO₂ and having a crystallinity of from 10 to 90%.

38. The diffusion plate according to claim 37, comprising as a main crystal an Al—Si—O-based crystal.

39. The diffusion plate according to claim 37, comprising as a main crystal an R—Al—Si—O-based crystal.

40. The diffusion plate according to claim 37, comprising as a composition, in terms of mass %, 45 to 75% of SiO₂, 13 to 30% of Al₂O₃, and 0 to 30% of Li₂O+Na₂O+K₂O+MgO+CaO+SrO+BaO+ZnO.

41. The diffusion plate according to claim 37, comprising as a composition, in terms of mass %, 45 to 70% of SiO₂, 13 to 30% of Al₂O₃, and 1 to 35% of Li₂O+Na₂O+K₂O+MgO+CaO+SrO+BaO+ZnO.

42. The diffusion plate according to claim 37, wherein the diffusion plate has an average crystal grain size of a main crystal of from 20 to 30,000 nm.

43. The diffusion plate according to claim 37, wherein the diffusion plate has a haze value of 10% or more.

44. The diffusion plate according to claim 37, wherein the diffusion plate is used for an illumination device.

45. An illumination device, comprising the diffusion plate according to claim 37.
